(19) United States
(12) Patent Application Publication
(10) Pub. No.: US 2003/0126533 A1
(43) Pub. Date: Jul. 3, 2003

(54) Testing of circuit modules embedded in an integrated circuit

(76) Inventor: Mark Alan McAdams, Plano, TX (US)

Correspondence Address: MICHAEL O. SCHEINBERG, P.O. BOX 164140, AUSTIN, TX, 78716-4140, US

(21) Appl. No.: 10/033,007

(22) Filed: Dec. 28, 2001

(51) Int. Cl. G01R 31/28

(52) U.S. Cl. 714/727

(57) ABSTRACT

A system is provided for independently testing a circuit module embedded in a larger integrated circuit, such as a system of a chip. The system uses essentially the circuit board level JTAG standard originally created to test chips mounted on a circuit board. The system provides a scan ring for serially scanning data to the inputs of the circuit module and for serially scanning out output from the circuit module. A test access port provides communications and control from an off-chip test interface to the scan rings.

### TECHNICAL FIELD OF THE INVENTION

The present invention relates to the field of integrated circuit design and testing and in particular, to testing of circuit module embedded in an integrated circuit.

### BACKGROUND OF THE INVENTION

Integrated circuit design and manufacturing are incredibly complex operations. A circuit design, which begins as a functional description of circuit logic, must be converted into circuit components, such as transistors, resistors, capacitors, and connecting wires, formed from areas of conductors, semiconductors, and insulators on a semiconductor substrate. Multiple copies of the circuit are typically produced on a silicon wafer, which is then cut up or “diced” into chips or die, each containing a copy of the circuit.

After extensive testing shows that the design faithfully performs the logic of the design, the circuit is fabricated as a physical circuit on the semiconductor substrate. The physical circuit does not behave like an assembly of ideal logic components, so a design that works in theory may not work when produced as a physical device. For example, the capacitance between adjacent conductors affects the circuit operation, as does the time required for electronic signals to move between elements in the circuit. Additional extensive testing and analysis is performed as the circuit logic is converted into a circuit design and then into physical circuits.

The computational power of computers, which depends on the number of logic elements in an integrated circuit, doubles approximately every eighteen months. This doubling is due fabrication advances that shrink the size of circuit elements. As the capability of integrated circuits (IC) fabrication processes advance, the number of transistors and logic gates that can be applied on a semiconductor chip increases exponentially. Current integrated circuits include tens of million of logic gates on a single chip.

One consequence of decreased feature sizes is that an ever-increasing amount of circuitry can be fabricated on silicon chip of a given size. Designers can combine within a single chip all the functions of a traditional system, including processors, digital signal processors (DSP), memory, and peripheral interfaces. It takes designer time, however, to design and test all the new circuits. It is critical that design time be keep low so that new products can be brought to market as quickly as possible so there is little time available to design new circuitry to fill the available space. While the productivity of circuit designed is estimated to be increasing at about twenty percent a year, this is insufficient to take advantage of the available space on the chips in time to meet the market demand.

The number of designers is not growing appreciably, and current designers are not able to keep up with the increased capacity of the chips. For example, many semiconductor houses have the silicon process complexity to put more than twenty million logic gates on a chip. However, the average application specific integrated circuit (ASIC) today includes roughly five hundred thousand gates. It is widely recognized that a productivity gap exists between the capabilities of today's electronic design automation (EDA) tools and the number of gates available on a single die in the current silicon processes.

To overcome this resource gap, designers seek to create multi-million gate system-on-chip (SoC) designs by reusing existing, pre-verified design modules, referred to as circuit modules, intellectual property (IP) modules, IP cores, or blocks. A circuit module typically includes input and output connections, sometimes referred to as pins. A specification for a module prescribes what will come out of the module for a given input. FIG. 1 shows an example of circuit modules 10, 20, and 30 on a single chip 40. Circuit module 10 has inputs 12 and outputs 14. Circuit module 20 has inputs 22 and outputs 24. Circuit module 30 has inputs 32 and outputs 34. Chip input pins 50 and output pins 52 connect chip 40 to the outside world.

When a design team creates a circuit design, whether a module or an independent circuit, the team typically creates a set of tests for verifying that the physical circuit is producing the results that the designer intended. A typically test consists of a series of test vectors, that is, a series of ones and zeros that are applied to the input connections of the circuit. The output connections of the circuit are sensed to confirm that the output agrees with the predicted output.

Chips have metal pins for sending and receiving electrical signals onto and off of the chip, thereby allowing a computer or other device to communicate with the chip. The overall system on the chip can be tested by applying test vectors to the input pins and observing the output on the output pins.

Design modules embedded in a larger chip design also have designated input and output connections, but the connections do not necessarily correspond to pins that connect off of the chip. Many of the design modules will receive some of their input signals and provide some of their output signals to and from other internal design modules, rather than to or from a connection off the chip. It can be extremely difficult to separately test a design module on a chip when its inputs and outputs are not directly accessible for applying a test vector and sensing the results.

In FIG. 1, for example, input pins 12 of circuit module 10 connect to chip input pins 50, but output pins 14 connect to circuit module 20 and circuit module 30, and not to output pins 52. Thus, it would be difficult to detect the output of circuit module 10 when a test vector is applied to its inputs. Similarly, some of the outputs 34 of circuit module 30 are connected to output pins 52 and so can be readily sensed, but some of the inputs 32 come from circuit module 20 rather than input pins 50, so it would be difficult to apply a test vector to the inputs 32 of circuit module 30.

One possible solution would be to provide extra pins on the chip so that every input or output of every circuit module has a separate pin and can be independently tested. In complex chips, however, the number of pins would be so large that they could not be accommodated on the chip.

Another option, known as parallel test vector insertion, is to multiplex the chip pins so that they can be switched to communicate to different parts of the chip. During test mode, the chip can then be configured so that some of the chip input and output pins connect directly to and from the module being tested. Test vectors can be applied directly to the design module and output can be sensed.

Another option for testing embedded modules is to use a serial scan chain. In a serial scan chain, signals for the inputs of a design module are fed in sequentially though one of the pins on the chip. The signals are stored at multiple storage locations corresponding to inputs of the circuit module. As each new signal is input, the signals sequence through the storage locations corresponding to the circuit module inputs. When the proper signal is positioned at each of the inputs, the stored signals are captured applied to the design module inputs. Similarly, the design module outputs are stored at each of the outputs, and then serially passed off the chip to a computer that reconstructs the output from the signals.

Although serial scan chains require less wiring that parallel test vector insertion and can therefore handle more circuit modules on a chip, it takes time to scan the test vector around the chain, which reduces the number of tests that can be run.

### SUMMARY OF THE INVENTION

An object of the invention is to provide a method and apparatus for testing circuit modules embedded into larger circuits.

The present invention allows an individual circuit module to be tested independently of the rest of the chip. The invention uses a boundary scan register added to the circuit module to allow test vectors to be serially input through a chip I/O pins and then applied to the circuit module inputs upon application of a control signal. The boundary scan register similarly allows the output of the circuit module to be stored and then serially scanned off the chip through chip I/O pins. Each of the module's internal connections can be made available for testing. The testing data and control are sent into the chip using a small number of pins that can be dedicated test pins or pins that function differently in test mode and in normal operation.

The preferred embodiment uses a circuit board-level test protocol and uses it, with or without modifications, for testing circuit modules on a single chip. A preferred embodiment uses the well-known JTAG protocol, but applies it at the chip level instead of the board level. Using a known protocol allows designers to build upon their existing knowledge and tools when implementing while providing new test capability at the chip level.

The foregoing has outlined rather broadly the features and technical advantages of the present invention in order that the detailed description of the invention that follows may be better understood. Additional features and advantages of the invention will be described hereinafter. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more thorough understanding of the present invention, and the advantages thereof, reference is now made to the following descriptions taken in conjunction with the accompanying drawings, in which:

FIG. 1 shows a typical circuit module embedded in a system-on-a-chip.

FIG. 2 shows a test logic added to an input pin in a preferred embodiment.

FIG. 3 shows a test logic added to an output pin in a preferred embodiment.

FIG. 4 shows a test logic added to a bi-directional pin in a preferred embodiment.

FIG. 5 shows a boundary scan register around a circuit module in a preferred embodiment.

FIG. 6 is a test access port used in a preferred embodiment.

FIG. 7 shows the inputs and outputs of a test vector conversion program.

FIG. 8 shows a timing diagram for inputting and outputting data to a typical integrated circuit.

FIG. 9 is a flowchart showing the steps for implementing a preferred test system of the present invention in a chip design.

FIG. 10 is a flowchart showing the steps for using a preferred embodiment of the invention.

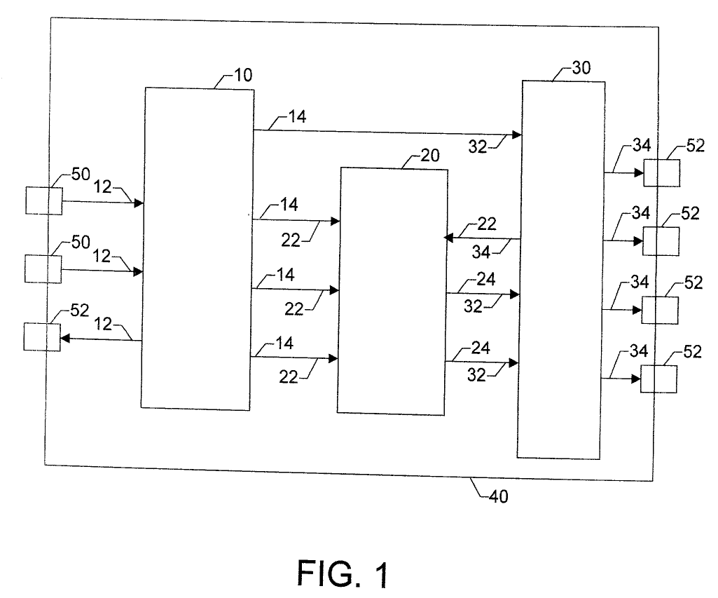

### DETAILED DESCRIPTION OF THE PREFERRED EMBODIMENTS

A preferred embodiment of a system used to test circuit modules embedded in a larger circuit design is similar to the system described in IEEE 1149.1 JTAG standard. JTAG is a well-known standard for testing integrated circuits that are mounted on a circuit board. The JTAG standard tests chips whose leads may not be directly assessable from connections off the circuit board; the invention tests circuit modules whose leads may not be accessible from connection off the chip.

JTAG uses a boundary scan register incorporated into each chip. The boundary scan register includes a cell at each input lead and each output lead so that data can be serially scanned to the inputs and from the outputs. The test is controlled through five pins that are designed into each chip and accessed through the circuit board. Three of the pins are used for a clock signal (TCK), a reset signal (TRST), and a test mode signal (TMS), all of which are sent in parallel to the boundary scan register of each chip having a JTAG interface. The other two pins are for input signals (TDI) and output signals (TDO). The inputs and outputs for all the boundary scan registers of the JTAG-capable chips on the board are connected in a single serial scan chain, that is, the data out (TDO) from the boundary scan register of one chip becomes the data in (TDI) for the boundary scan register of the next chip, and data is serially scanned through each JTAG-enabled chip on the board before it exits the board.

The JTAG protocol includes a series of commands used by a test designer to define and deliver the test vectors and to view the results. Each JTAG-capable chip samples the TMS line as the TCK signal cycles, and the TMS signal indicates whether the data on the TDI line corresponds to a command, which is to be routed to an internal command register, or to data, which is to be routed through the scan chain. The tester first sets up the instructions for all chips on circuit board. Data is then scanned through the boundary scan registers according to the instructions provided.

All chips on the circuit board, except the one that is to be tested, receive a scanned in by-pass command, so that only the chip to be tested processes the test vectors. The chips in BYPASS mode do not scan data through the entire scan chain in their boundary scan registers, but simply pass the TDI signal to the TDO line with a one clock cycle delay. By knowing the ordering of all the boundary scan registers and knowing which devices are in BYPASS mode, the tester can test a specific chip by determining how many clock cycles to delay the data to be scanned in and how many clock cycles to wait for valid data to be scanned out.

The physical implementation of board-level JTAG logic, in which the serial scan chain includes all the boundary scan registers, would be slow and unwieldy to implement at each one of the multiple circuit modules on a chip. A preferred embodiment of the invention implementing JTAG at the chip level reduces the amount of additional logic circuitry required and improves performance by scanning data only to and from the individual circuit module under test, rather than scanning data around all the embedded circuit modules.

In a preferred embodiment, signals can be applied to each input or bi-directional connection of a circuit module, and signals can be sensed at each output or bi-directional connection. The circuit module can therefore be tested independently of the system in which it is embedded. The design of the chip in which the circuit module is embedded is modified to incorporate test logic. The test logic includes circuit module test logic associated with each circuit module and global circuit test logic that controls the circuit module test logic at each circuit module and that coordinates communication onto and off of the chip. During normal operation, the circuit module test logic is transparent, that is, it allows each connection of the circuit module to send or receive signals to or from its normal connecting part. During test mode, controls signals and data flow from outside of the chip through the global test logic to the circuit module test logic and then to and from the connections on the circuit module.

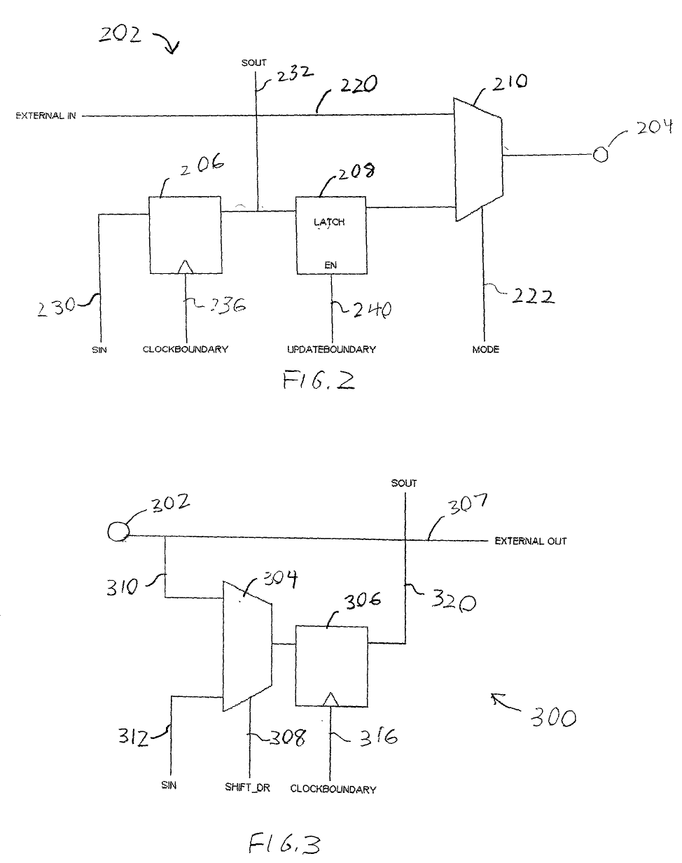

FIG. 2 shows the input test logic 202 that is added for each input pin 204 of the circuit module. (The term “pin” when used in connection with an embedded circuit module refers to connection from the circuit module to other components on the chip, and not necessarily to a physical pin that connects off the chip.) Input test logic 202 includes a scan latch 206, an application latch 208, and a data selector 210. Scan latch 206 receives an S_{IN} signal on line 230 and outputs an S_{OUT} signal on line 232 to application latch 208 and to the next scan latch in the chain when a CLOCKBOUNDARY signal is received on line 236. Application latch 208 passes a signal from scan latch 206 to the circuit module input pin 204 when an UPDATEBOUNDARY signal is received. Data selector 210 applies to the circuit module connector either an external signal from line 220 when MODE line 222 indicates that the circuit module in normal operation mode, or the signal from application latch 208, when MODE line 222 indicates that the circuit module is in test mode and an UPDATEBOUNDARY signal is received. The lines Sₒᵤₜ from one latch become the line S_{IN} to the next latch in the scan chain.

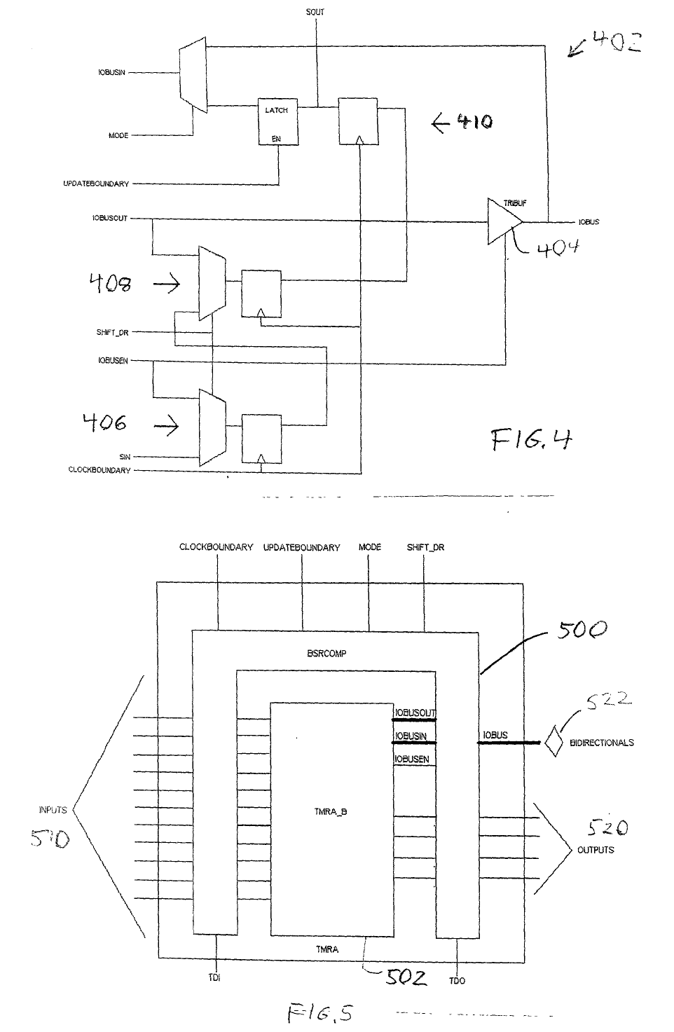

FIG. 3 shows the additional test logic 300 that is added for each output pin 302 of the circuit modules to be tested. Output test logic 300 includes a data selector 304 and a scan latch 306. The output signal from output pin 302 connects to both its normal output path 307 and to data selector 304. When a SHIFT_DR signal is applied on line 308, data selector 304 passes to latch 306 the output from the circuit module connector on line 310. Otherwise, data selector 304 passes to latch 306 the signal S_{IN} on line 312 from a previous latch in the scan chain. When a CLOCKBOUNDARY signal is received on line 316, the data in latch 306 is sent over line 320 to the next latch in the scan chain and data from the previous latch in the scan chain, or from output pin 302, is stored in latch 306.

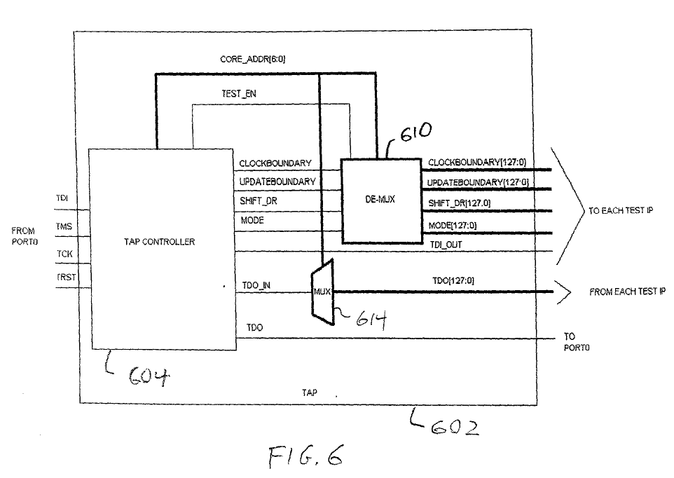

FIG. 4 shows the additional test logic 402 that is added to each bi-directional pin of the circuit module. Test logic 402 includes a tri-state buffer 404; output cells 406 and 408, each of which is similar to test logic 300; and an input cell 410, which is similar to test logic 202. Input cell 410 allows data to be input into the bi-directional pin. Output cell 406 captures the tristate control value and output cell 408 captures the output data. The state of the tristate buffer 404 is controlled by the circuit module under test in accordance with whether the circuit module is using the bi-directional pin as an input pin or an output pin.

When the internal logic of the circuit module forces the tristate control (IOBUSEN) high, it will cause tristate buffer 404 to enable, indicating that the circuit module under test is wanting to output data on the bi-directional pin. When the subsequent scan is examined, the IOBUSEN bit will be set high, indicating that the data captured in output cell 408 connected to IOBUSOUT is valid, and any data in input cell 410 cell was not applied and can be ignored. A scan showing IOBUSEN low means the circuit module wants data, and the data to be input should be scanned into the input cell 410.

The state of the bi-directional pin is based purely on the test vectors. In typical test vector application, a “1” means drive it high and an “H” means measure it high. A “Z” means the pin is currently in tristate mode and an “X” means it is a don't care. If the test vector for a bi-directional has an “H” in it, it means that when a scan is performed, the IOBUSEN should be high, the IOBUSOUT connected to output cell 408 should be measured high, and nothing should be driven into IOBUSIN. If the test vector indicates a “1”, it means a low should be measured on IOBUSEN (because it should be driving in), the value for IOBUSOUT on that output cell 408 should be ignored, and a value of 1 should be placed into the input cell 410 cell for IOBUSIN. In other words, output cell 406 is only used to determine whether the device wants to get or send data, and the values in the test vectors (which do not have tristate controls) should reflect whatever the value on IOBUSEN is. That is, the state of the buffer is measured to make sure that the test vectors being applied are correct, i.e., if IOBUSEN is high, then the test vector for the bidirectional should be a “measure output” value. If IOBUSEN is low, then the test vector for the bidirectional should be “force input.”

FIG. 5 shows a boundary scan register 500 around an exemplary circuit module, timer 502. Boundary scan register 500 is composed of test logic 202 at each of input pins 510, test logic 300 at each of output pins 520, and test logic 402 at each bidirectional pin 522. Details of the test logic are not shown in FIG. 5. The inputs 510 into the boundary scan register include the non-test inputs into the circuit module 502, the test data signals, TDI and TDO, and test control signals, MODE, SHIFT_DR, CLOCKBOUNDARY and UPDATEBOUNDARY.

The TDI and TDO lines are used for data in and data out, respectively. The first latch in the boundary scan register of a circuit module connects to the TDI line, and the last in the scan chain connects to the TDO line. As described above with respect to FIG. 2, depending upon the state of the MODE line, the input to circuit module 502 can come from normal inputs 510 transparently through boundary scan register 500 or, in test mode, the input can be sequentially scanned into boundary scan register 500 through the TDI input. As described above with respect to the output test logic 300, the SHIFT_DR line is used to signal when data at the outputs are to be captured, the CLOCKBOUNDARY line is use to convey a clock signal, which moves data along the scan chain as it toggles, and the UPDATEBOUNDARY line is used to indicate that the data stored in the scan chain is to be applied to the circuit module input pins 204, as described with respect to FIG. 2.

The test data and control signals come to the circuit module from an off chip test interface and through a test controller referred to as a test access port (TAP) 602 shown in FIG. 6. TAP 602 communicates to the world outside the chip using five conductors: TDI, TMS, TCK, TRST, and TDO. These lines and their commands function in the same manner as their analogs in board level JTAG. In a preferred embodiment, however, user-defined JTAG functions are used to address individual circuit modules.

As described with respect to boundary scan register 500, the TDI and TDO lines are used for test data in and test data out, respectively. The TCK is a free running clock, and the TRST is a reset line used to reset the test system before applying a series of test vectors. The TMS line is used as a delimiter to identify a series of signals on the TDI line as a single group of information. For example, a change in the TMS may indicate that one series of bits on the TDI represents data and another series of bits represents a control command.

Each of these five conductors is connected to a pin on the chip that is accessible to the off-chip test interface, and all test information and test control signals are routed through those five pins. The five pins can be dedicated pins that are used only for testing, or the pins can be used by other resources during normal operation and switched to function as test pins when the chip is put into test mode. Skilled persons will be able to design circuitry for sharing pins between different functions.

TAP 602 includes a TAP controller 604, a demultiplexer 610 for sending control signals to a selected circuit module, and a multiplexer 614 for receiving signals from the selected circuit module. The TAP controller 604 includes logic for interpreting and executing test program instructions from the test interface. TAP controller 604 uses nine lines for signals for controlling the test and transmitting test data to each circuit module. The lines include a CORE_ADDR, TEST_EN, CLOCKBOUNDARY, UPDATE BOUNDARY, SHIFT_DR, and MODE line. The function of the CLOCKBOUNDARY, UPDATE BOUNDARY, SHIFT_DR, and MODE lines were described previously. There is a separate set of these four conductors from de-multiplexer 610 to the boundary scan register 500 of each of the circuit module 502. De-multiplexer 610 places the test signals on the appropriate one of the sets of four conductors in accordance with the circuit module address received from TAP controller 604. This contrast to the JTAG standard in which the TCK, TMS, and TRST lines go in parallel to each of the boundary scan register

In a preferred embodiment, each circuit module has a designated address, and the CORE_ADDR lines transmit to de-multiplexer 610 and to multiplexer 614 the address of the circuit module is to be tested. The TEST_EN line indicates to de-multiplexer 610 whether the system is in test mode. When TEST_EN is not active, all of the outputs of demultiplexer 610 are forced inactive, or low, and data coming into the TAP controller 604 on TDO is ignored. The CORE_ADD lines preferably comprise a set of six conductors and can be used to address up to 128 circuit modules. Data is sent from TAP 602 over a single TDI_OUT conductor that connects to the boundary scan registers of all the testable circuit modules. Although data is sent to all the boundary scan registers, only the boundary scan register of the circuit module under test receives the CLOCKBOUNDARY, UPDATE BOUNDARY, SHIFT_DR, and MODE signals and so only the circuit module under test will shift the data through its scan chain and apply data to circuit module inputs. There are also individual conductors from each circuit module for carrying data to the TAP 602. Multiplexer 614 selects the data line from the circuit module being tested in accordance with the CORE_ADDR signal and forwards the signal to the TAP controller 604, so that it can be output off the chip as the TDO signal.

The tests written for each circuit module are typically designed to be applied directly to the connections of the circuit module. To be used with the present invention, the set of test vectors must be converted to serial form and the appropriate control signals inserted for scanning the test vectors into the boundary scan register around the circuit module, applying the test vector, and retrieving the circuit module output.

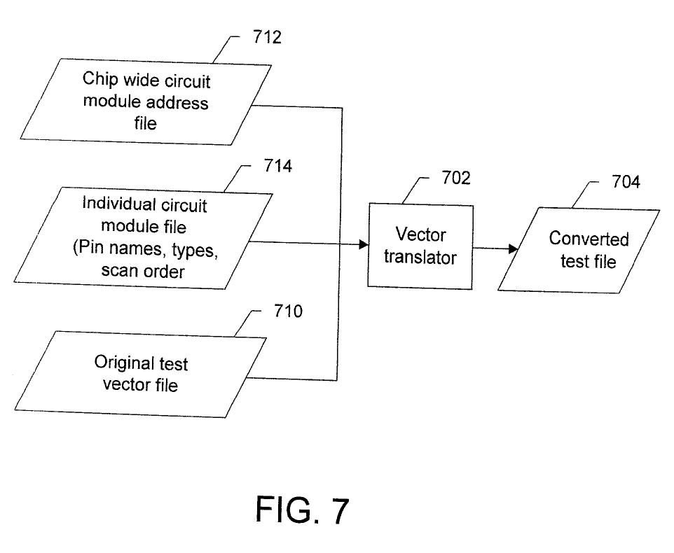

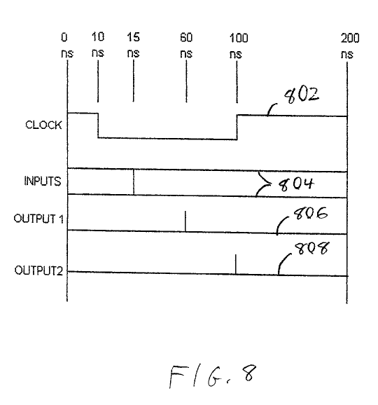

FIG. 7 shows a vector translation program 702 that produces a converted test file 704 for use with the invention from an original test vector file 710, a chip wide circuit module address file 712, and an individual circuit module file 714. Because the TAP controller references the individual circuit modules using an address, vector translation program 702 requires the address for each circuit module. The address information is obtained from the chip-wide circuit module address file 712, which is usually created by a circuit designer when the test logic is added to the chip.

Because the test vectors are sequentially scanned into the scan chain, the conversion program needs to know the relative location of each circuit module pin in the scan chain. The individual circuit module file 714 indicates the order in which the connections of the circuit module are connected in the scan chain, the type of pin (input, output, or bi-directional) and the name of the pin. Individual circuit module file 714 may be created when a circuit designer modifies a circuit module to insert a boundary scan register.

The conversion program must also ensure that events in the testing occur in the correct sequence. In the normal operation of an integrated circuit, clock pulses coordinate activity between different circuit sections. Events, such as data writing, reading, and transfer, are scheduled to occur in relation to a clock pulse. For example, FIG. 8 shows a typical timing diagram that includes a clock timing graph 802, inputs timing graphs 804, a first output timing graph 806 and a second output timing graph 808. Clock timing graph 802 shows that a clock pulse goes from high to low at 10 ns after the start of a timing cycle. At 15 ns into the timing cycle, graph 804 shows that the inputs are applied. At 60 ns into the timing cycle, graph 806 shows that the first outputs are strobed, and at 100 ns into the timing cycle, graph 802 shows that the clock returns to high and graph 808 shows that the second output is strobed.

When executing a test vector on a free standing circuit, the inputs and outputs can be applied or read at the proper time during the clock cycle. When the inputs and outputs are applied or read through a serial scan chain, it is impossible to perform all the operations required in a single clock cycle, since multiple clock cycles are required just to input a command to the TAP controller or to shift in a test vector to input pins and to retrieve the output data. When using a serial scan chain the timing of the chip operation is “stretched,” that is, the time between events of the clock cycle are extended, but the circuit is properly tested if the events occur in the proper relation to each other.

For example, in the timing diagram of FIG. 8, the low-going clock pulse at 10 ns is scanned into the boundary scan register of the circuit module under test through the scan chain and applied to the clock input of the circuit module. As the clock pulse is held low, the inputs are scanned in through the scan chain and applied. Next the first output is sensed and passed out through the scan chain. Finally, the upgoing clock pulse is scanned in and applied simultaneously with sensing the second output, which is then scanned out.

Although the actual durations of the timing diagram, such as 15 ns or 60 ns times for input and output, are not followed in the test, the order of events is maintained. In this example, four scans are required for each pattern to apply the input stimulus in the proper order and to obtain the output data in the proper order. For each test vector, the converter program determines the number of scan cycles required to apply all inputs and strobe all outputs. It then converts each vector line to that number of scan cycles, applying the data in proper format for transmitting through the TAP controller and inserting appropriate control signals to instruct the TAP controller.

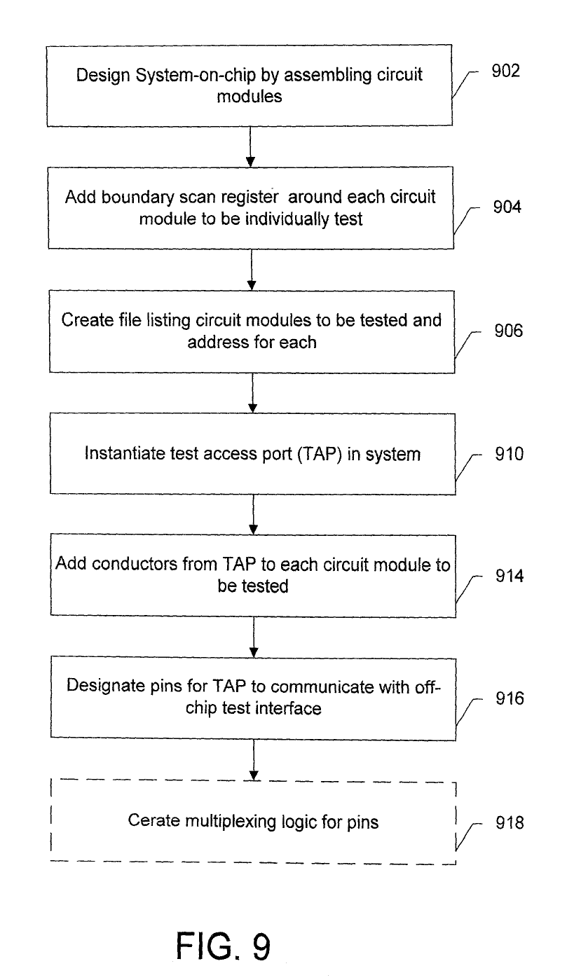

FIG. 9 shows the steps of a circuit designer in implementing the present invention. Step 902 shows the designer assembling the circuit modules and adding other logic to create an integrated circuit, such as a system-on-a-chip. Test logic is then added to the chip. The test logic, including the boundary scan register and TAP is typically created and stored in libraries. The logic can be added to a chip design by instantiation of a library component when assembling circuit modules into a system. The test logic could also be added to an existing chip. Step 904 shows the circuit designer instantiates from the circuit library a boundary scan ring around each module that he desired to have the capability to independently test. In step 906, the designer creates a chip wide circuit module address file 712 (FIG. 7) listing the circuit modules used in the design, and designating an address for each. The addresses are used in the instantiations from the circuit library of a TAP in step 910. In step 914, the designer creates the conductors between the TAP and the boundary scan registers at each circuit module. In step 916, the designer designates pins on the chip that will connect to the TAP. In optional step 918, the designer adds multiplexing logic if the TAP is required to share pins with existing functions.

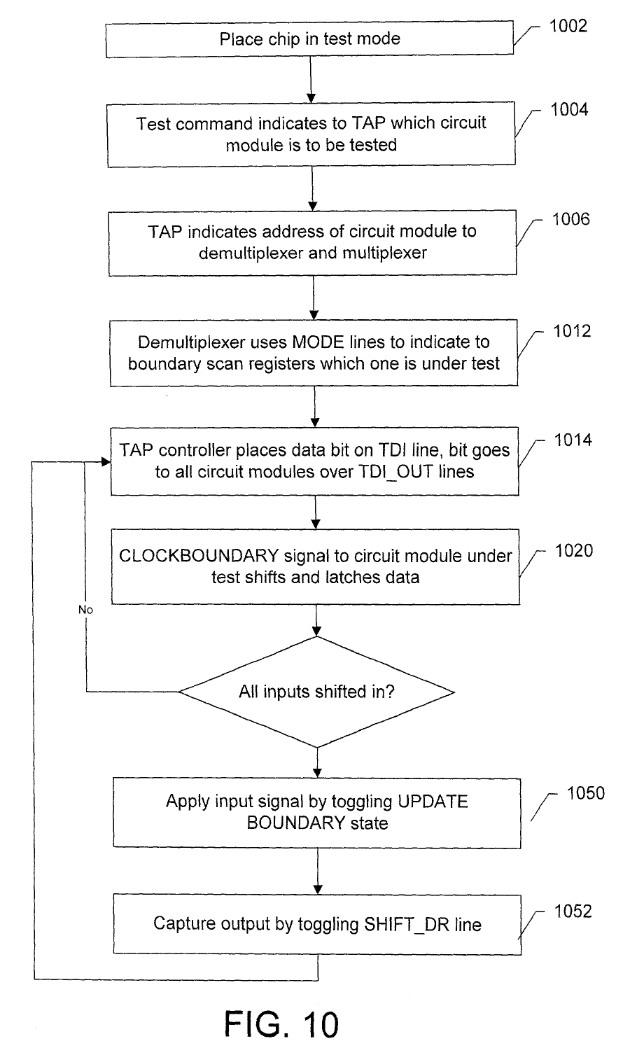

FIG. 10 shows the preferred steps of using the invention to test a circuit module. The steps are performed automatically by a test program generated by the converter test program. The steps described are nearly identical to the steps that would be used in a board level test using the JTAG protocol. In step 1002, the chip is placed into test mode by sending a command from a test interface. If the five test lines have dedicated pins on the chip, the test mode can be activated by applying a signal to TAP controller through the TMS (test mode select) line. If the five JTAG lines do not have dedicated pins on the chip, a signal can be applied to another data line, the signal being recognized by a processor that switches the chip into test mode and allocates five pins for the test interface.

In step 1004, the address of the circuit module to be tested is indicated to the TAP controller by a test command. In step 1006, the TAP controller indicates to the de-multiplexer 610 and the multiplexer 614 the address of the circuit module under test. In step 1012, the de-multiplexer indicates on the MODE line to the circuit module under test that it is under test; the state of the MODE for other circuit modules indicates to them that they are not under test, so signals from their boundary scan registers do not flow through their data selectors 210 (FIG. 2) to their input pins 204 (or bi-directional pins functioning as input pins) of the non-testing circuit module.

In step 1014, the TAP controller 604 then places the first bit of data from the TDI line onto the TDI_OUT line, which connects to all of the circuit modules. Data coming in from the test interface is recognized by a toggling of the state of the TMS line to indicate starting and stopping of data and instructions. For example, the TMS line may be in one state while all the data for the inputs are sequentially scanned in. The TMS line would change state to indicate, for example, completion of the scan. Changes in the state of the TMS line also indicate whether groups of data coming in over the TDI line represent instructions or data.

The CLOCKBOUNDARY signal to the circuit module under test causes the data bit on the TDI_OUT line to be latched into the first latch of the boundary scan register in step 1020. Each circuit module under test has its own CLOCKBOUNDARY line, and the CLOCKBOUNDARY signal is placed only on the CLOCKBOUNDARY line going to the circuit module under test, so the data is only latched in that circuit module. Steps 1014 and 1020 are repeated, with the next data bit of the test vector being then placed on the TDI_OUT line and, at the next clock cycle, the data bits are shifted, that is, the first data bit is shifted into the second latch of the boundary scan register and the second data bit is shifted into the first latch of the boundary scan register. Steps 1014 and 1020 are repeated, with the CLOCKBOUNDARY line toggling as data bits are fed in the TDI_OUT line, until the test vector is positioned at the appropriate input connections of the circuit module under test.

In step 1050, the UPDATEBOUNDARY signal is applied, causing the signals stored in latches at the input pins to be applied to the circuit module inputs. In step 1052, a SHIFT_DR signal is applied to latch in output latch 306 the state produced by the test vector input at the output pin 302 of the circuit module. As new data entered the scan chain in step 1014, the output captured in step 1052 continues through the scan chain until it exits the chip through the TDO line. Steps 1014 through 1052 are repeated until all the test vectors are scanned in and applied, and all the output data is scanned out. Step 1052 is skipped in some cycles, such as at the 10 ns point on FIG. 8, when there is no output to be sensed at that step.

For example, to implement the timing diagram of FIG. 9, a first cycle scans in and applies the low going clock signal as input to the circuit module under test. A second cycle scans in and applies the inputs. A third cycle does not scan in any new data, but captures output (step 1052). The last cycle scans in the up-going clock signal and captures output. The scan chain is continuous, with data moving between the latches at every clock cycle, regardless of whether the data coming out at the end of scan chain represents the sensed output signals or merely the continuation of input signals through the scan chain. Data is scanned in and output is scanned out through the same scan chain. The test interface keeps track of which signals coming out through the TDO line represent circuit module output data latched in response to the SHIFT_DR signal.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

We claim as follows:

1. A method of testing a circuit module embedded in an integrated circuit, at least some of the pins of the circuit module not being directly connected to a pin of the larger design, the method comprising:
communicating test commands and data using a board-level test protocol through a test interface by;
scanning test vector data into a scan chain associated with the inputs of the circuit module;
applying the test vector data in the scan chain as input to the circuit module; and
retrieving the output of the circuit module through the scan chain to the test interface.

2. The method of claim 1 in which communicating test commands and data includes communicating test commands and data from off the integrated circuit using five conductors including a clock conductor, a test mode conductor, a reset conductor, a data in conductor and a data out conductor.

3. The method of claim 1 further comprising converting a test vector into a series of JTAG protocol test commands and data, the JTAG command including a user defined command for defining an address for a circuit module.

4. The method of claim 3 in which converting a test vector includes maintaining timing relationships actions initiated by the test commands.

5. The method of claim 1 in which scanning test vector data into a scan chain includes scanning the test vector data to a single boundary scan register, the single boundary scan register being associated with the circuit module under test.

6. The method of claim 1 in which retrieving the output of the circuit module through the scan chain to the test interface includes scanning the output of a boundary scan register to the test interface without scanning the output through a second boundary scan ring.

7. The method of claim 1 in which retrieving the output of the circuit module through the scan chain to the test interface includes scanning the output of a boundary scan register through at least one dedicated output conductor.

8. A system for testing one or more of multiple circuit modules embedded in an integrated circuit, comprising:
a test controller for accepting serial data and control signals from outside the integrated circuit in accordance with a test protocol that corresponds to a board level test protocol, the controller including;
a first selector for selecting one of the multiple circuit modules for testing, control signals being transmitted to only the selected one of the test modules; and
a second selector for selecting output from the selected one of the circuit modules; and
a boundary scan register corresponding to each of the one or more circuit modules, the boundary scan register providing input to circuit modules from the controller in a test mode and from an operating input when in operating mode.

9. The system of claim 8 in which the test controller includes logic for using serial data and control signals in accordance with a JTAG protocol.

10. The system of claim 8 further comprising multiple sets of four conductors, one set connecting the selector to each of the boundary scan registers.

11. The system of claim 10 in which the four conductors include a clock line, an update line, a mode line, and a data capture line.

12. The system of claim 10 further comprising a data input line that connects from the test controller to every boundary scan register.

13. The system of claim 10 further comprising multiple data output lines, each connecting from a different boundary scan register to the second selector.

14. The system of claim 8 in which each boundary scan register includes test logic for each input pin, output pin, and bi-directional pin of the corresponding circuit module, the test logic for each input pin including a latch for scanning in data, a latch for applying data, and a data selector for selectively conveying data from the latch to the input pin.

15. The system of claim 8 in which each boundary scan register includes test logic for each input pin, output pin, and bi-directional pin of the corresponding circuit module, the test logic for each output pin including a latch for scanning data and a selector for selectively storing in the latch output from the output pin or data from the scan chain.

16. The system of claim 8 in which each boundary scan register includes test logic for each input pin, output pin, and bi-directional pin of the corresponding circuit module, the test logic for each bi-directional pin including tri-state buffer.

17. The system of claim 8 further comprising five conductors for conveying data and control signals from the test controller to the test interface.

18. The system of claim 17 in which the five conductors include a data in line, a data out line, a clock line, a test mode set line, and a reset line.

19. A system for testing one or more of multiple circuit modules embedded in an integrated circuit, comprising:
a test controller for accepting serial data and control signals from a test interface in accordance with a test protocol that corresponds to a board level test protocol; and
a boundary scan register corresponding to each of the one or more circuit modules, the boundary scan ring providing input to circuit modules from the controller in a test mode and from an operating input when in operating mode.

20. The system of claim 19 in which the test controller includes logic for accepting serial data and control signals in accordance with a test protocol that corresponds to a JTAG protocol.

21. The system of claim 19 in which the test controller includes a selector for selecting one of the multiple circuit modules for testing, control signals being transmitted to only the selected one of the test modules.

22. The system of claim 19 in which a test controller for accepting serial data and control signals from a test interface in accordance with a test protocol that corresponds to a board level test protocol includes a selector for selecting output from the selected one of the circuit modules.

23. A system for testing one or more of multiple circuit modules embedded in an integrated circuit, comprising:
a test controller for accepting serial data and control signals from outside the integrated circuit, the test controller including logic for communicating with outside the integrated circuit using a clock line, a reset line, a test mode line, a data-in line, and a data-out line;
one or more multiple boundary scan register, each boundary scan register corresponding to one of the circuit modules, each boundary scan register providing input to the corresponding circuit module from the test controller when the integrated circuit is in a test mode and from an operating input when in the integrates circuit is in an operating mode; and
conductors for the test controller to communicate with the boundary scan registers, the conductors including a data-in line, a data-out line, a clock line, a mode line to indicate whether the integrated circuit module is in test mode or operating mode, an output data capture line indicating that output from the circuit module is to be captured, an input application line to indicate that input data in the boundary scan register is to be applied to the inputs of the circuit module.

24. The method of claim 23 in which the test controller includes logic for accepting commands and data formatted in a JTAG protocol.

25. A method of testing a circuit module embedded in an integrated circuit design, at least some of the pins of the circuit module not being directly connected to a pin of the larger design, test commands and data being communicated to the circuit module using five conductors including a clock conductor, a test mode conductor, a reset conductor, a data in conductor, and a data out conductor, the method comprising;
scanning through the data in conductor commands and data into a scan chain associated with the inputs of the circuit module;
applying the data in the scan chain as input to the circuit module; and
retrieving through the data out conductor output of the circuit module through the scan chain to the test interface.
